(19) United States
(12) Patent Application Publication
(10) Pub. No.: US 2006/0104103 A1
(43) Pub. Date: May 18, 2006

(54) Method for optical authentication and identification of objects and device therefor

(75) Inventors: Joseph Colineau, Bures Sur Yvette (FR); Jean-Claude Lehureau, Sainte Genevieve Des Bois (FR); Renaud Binet, Palaiseau (FR)

Correspondence Address: LOWE HAUPTMAN GILMAN & BERNER, LLP, 1700 DIAGNOSTIC ROAD, SUITE 300, ALEXANDRIA, VA, 22314, US

(73) Assignee: Thales, Neuilly Sur Seine (FR)

(21) Appl. No.: 10/539,767

(22) PCT Filed: Dec. 10, 2003
(86) PCT No.: PCT/EP03/50975

§ 371 Date: Jun. 20, 2005

(30) Foreign Application Priority Data
Dec. 20, 2002 (FR) 02 16366

(51) Int. Cl. G11C 5/06

(52) U.S. Cl. 365/71

(57) ABSTRACT

The method in accordance with the invention consists in illuminating with coherent light a volume-wise at least partially scattering surface of reference objects under specified illumination conditions, in recording the speckle patterns thus obtained for various nominal values of illumination parameters and in a range of values around these nominal values, then, upon the verification of other objects or of the same objects, in illuminating these objects under the same nominal conditions and in comparing each time the speckle pattern thus obtained with those which were recorded and in retaining the objects if their speckle pattern corresponds to one of those that was recorded.

### OBJECTS AND DEVICE THEREFOR

The present invention pertains to a method of optical authentication and identification of objects and to a device for implementing this method.

To authenticate an object, it is possible to incorporate therein a mark which is difficult to reproduce or to falsify, such as a holographic label, or else it is possible to structure in a particular manner its support material, for example, or else again, it is possible to include in the material of one of the parts of the object particles or components that can be sensed only by physical observation with the aid of special apparatus.

Patent GB 2 221 870 discloses a method of authenticating objects based on the observation of the “speckle” backscattered by a structure embossed on these objects, or else by the superposition of two materials of different refractive indices, or else by phase objects that are incorporated thereinto and which create scatter in the volume of one of their layers.

Moreover, for the authentication of bank notes, the direct use of the random structure of their support has been proposed and used, which structure is observed under incoherent light and associated with an electronic signature based on the encoding of the image with a public key encoding algorithm.

The authentication methods cited above require the modification of the objects to be authenticated, this not always being possible (works of art, fragile objects, etc.) or being applicable only to certain categories of objects (bank notes, etc.).

The subject of the present invention is a method of authenticating and/or identifying objects which requires no modification of these objects, which allows their definite authentication, which allows easy recognition of counterfeit objects, and which is easy to implement.

The subject of the present invention is also a device for authenticating and/or identifying objects which is easy to produce and to use, which may easily be adapted to any sort of object and which is as inexpensive as possible.

The method in accordance with the invention consists in illuminating with coherent light a volume-wise at least partially scattering surface of reference objects under specified illumination conditions, in recording the speckle patterns thus obtained for various nominal values of illumination parameters and in a range of values around these nominal values, then, upon the verification of other objects or of the same objects, in illuminating these objects under the same nominal conditions and in comparing each time the speckle pattern thus obtained with those which were recorded and in retaining the objects if their speckle pattern corresponds to one of those that was recorded.

The device in accordance with the invention comprises an optical recording device with laser source, a storage device and an optical reading device with laser source, parameters of these optical devices being modifiable.

According to a characteristic of the invention, the modifiable parameters of the optical devices are one at least of the following parameters: wavelength of the laser source, direction of emission of the laser beam, focusing of the laser beam, position of the laser source, inclination and position of the object with respect to the laser beam.

The present invention will be better understood on reading the detailed description of several embodiments, taken by way of nonlimiting examples and illustrated by the appended drawing, in which:

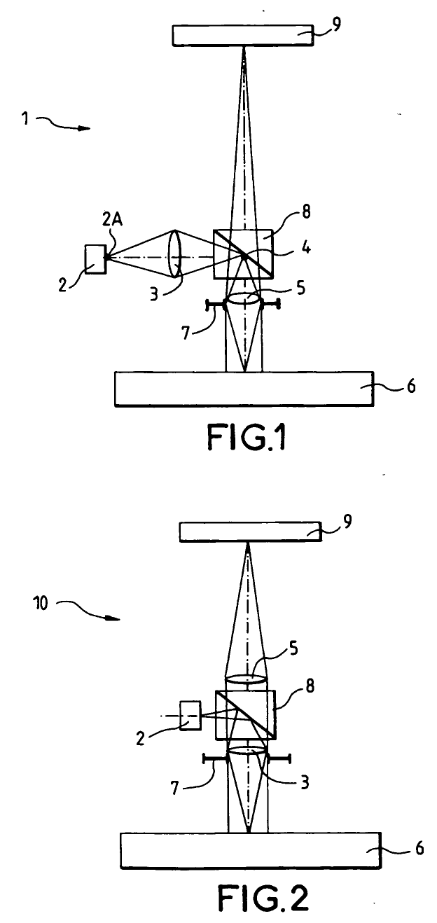

FIGS. 1 and 2 are block diagrams of two different embodiments of the optical reading device of the authentication and identification device in accordance with the invention,

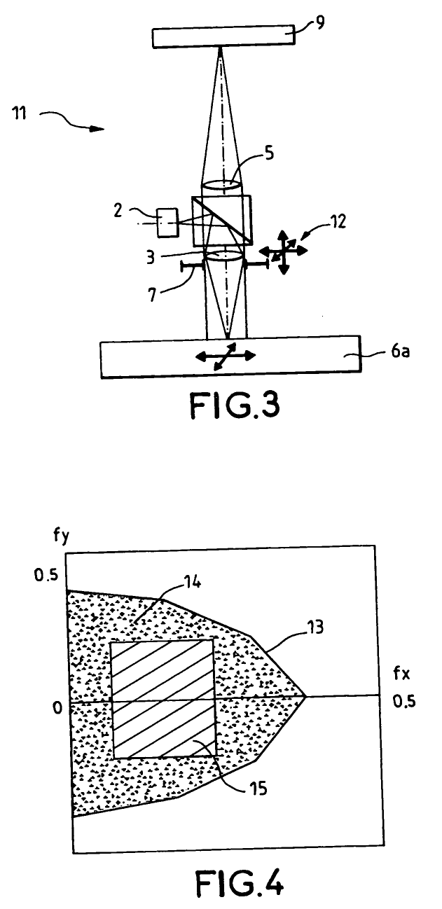

FIG. 3 is a block diagram of an embodiment of the optical recording device of the authentication and identification device in accordance with the invention,

FIG. 4 is a simplified view of a spectral domain of images serving to construct the references upon the recording of the speckle patterns according to the method of the invention, and

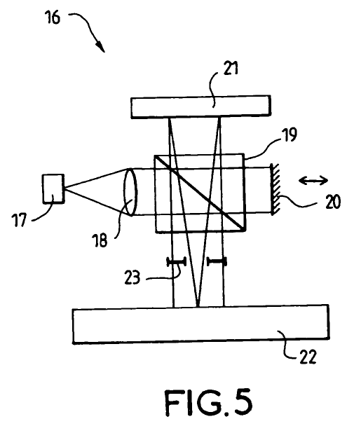

FIG. 5 is a simplified block diagram of an embodiment of an optical device in accordance with the invention for the recording of references by electronic holography.

The invention is directed both to the authentication and the identification of objects with the same recording and reading devices. Hereinafter, only authentication will be dealt with, for simplicity, it being understood that the same apparatus and methods apply to identification.

If one were to apply a known method of forming speckles on the surface of an object such as an opaque object or a phase screen, while complying when reading with approximately the same conditions of illumination as when recording, the same patterns would be obtained. However, the counterfeiting of such an object is relatively easy and can be done by various methods (molding, optical copying, etc.).

To ensure very good protection against counterfeiting, the invention makes provision to illuminate objects that scatter or partially scatter in their volume. Thus, the copying of these objects is made very difficult. However, the structure of the light scattered becomes much more sensitive to any variation of each of the observation parameters.

Thus, if the wavelength used during checking is different from that during recording, on account of the natural dispersions of the laser diodes of the illumination sources, the pattern observed is completely different from that recorded. If the device serving for the check (herein called the reading device) is the same as that which served for recording, good reproducibility may be expected. On the other hand, if one wishes to develop a system comprising several low-cost readers, it is necessary to solve this problem. The complexity of the structure of the speckles and its sensitivity to the various observation parameters depend on the characteristics of the scattering medium: its mean scattering wavelength, its absorption, the number and the geometrical characteristics of the inhomogeneities. If the design of the object to be protected is within one's control, it is possible to choose according to the application a weakly 3D medium (that is to say one that is strongly absorbing and weakly scattering) or, on the contrary a medium in which an illumination wave undergoes a complex path, with numerous scatterings, so that the probability of copying or of false decision is made low. It is also possible to alter the thickness of the area(s) where the scattering occurs.

The invention makes provision, by construction of the reading system, to reduce the number of parameters on which the result depends. Thus, an inclination-tolerant optical configuration is advantageously chosen. To reduce the effect of the parameters that cannot be completely controlled, the following characteristics are implemented:

The first of these characteristics consists in recording the speckle patterns with the various values that these uncontrolled parameters can take, for example when the wavelength of the coherent illumination beam can differ from one reader to another, the speckle patterns of an object are recorded for the various possible wavelengths when reading. This method requires a complex and expensive recording system, but the recording operation is one-off, or borne out with a small number of recording systems, while the readers are generally numerous and should be inexpensive. However, the speckle patterns may not be recorded for a large number of values of parameters, since the reference database for a given object would increase rapidly and could bring about a reduction in the performance during the recognition step.

The second of these characteristics consists, in the reading phase, in varying the parameter considered within the span of allowable values. Thus it is possible, by modifying the value of the current of the reader laser diode, to scan a small span of wavelengths. Among the parameters for which the invention makes provision to vary the value, are in particular: the focusing of the reading beam, the position of the illumination source, the inclination of the object with respect to this beam. Of course, the number of these parameters to be adjusted and the number of different values that they can take should preferably be kept to a minimum, since the complexity of the reader and the duration of the reading operation increase rapidly as a function of the number of parameters and of their various values.

According to a second mode of implementation of the invention, the system is made interactive by verifying that, for a given parameter, drawn randomly from the span of admissible values (for example in the case of a particular position of the reading system with respect to the object), the signal observed is indeed the one that is expected. It is thus possible to choose the security level desired: with one and the same system it is possible to favor swiftness of identification or authentication, or security by multiplying up the number of verificatory checks. This characteristic makes the method of the invention both robust and more difficult to tamper with.

An embodiment of the device of this invention for the application to a reader of badges or tickets allowing access to protected areas will now be described. Of course, the invention is not limited to this application, and may be implemented in numerous other applications requiring identification or authentication of very diverse objects (works of arts, bills, bank notes, etc.).

The recognition performance is related to the quantity of information gathered during the acquisition step.

This quantity I of information may be defined by the relation:

I=Log(a posteriori probability/a priori probability), the a posteriori probability being the probability that the object recognized is the right one, given the observation made, and the a priori probability is the probability that the observation that was made occurs.

To maximize the quantity of information of the acquisitions, it is necessary:

1) for the a priori probability to be as low as possible, this being obtained by choosing as large as possible a number of illuminated pixels, and by ensuring that the intensity values of these pixels are as mutually independent as possible (this not being the case if the size of the pixels is substantially smaller than that of the speckle grains);

2) for the a posteriori probability to be as large as possible. For this it is necessary for the measurement conditions to be reproducible enough for an object not to give results that differ too much over time or according to the reader.

It is understood that these two constraints act in opposite directions. Designing a system that allows a large number of independent pixels presupposes that the reproducibility of the system and the stability of the object are perfectly controlled. In practice, if one is able to acquire 10 000 independent pixels and if two possible states are defined by thresholding for each of these pixels, after a suitable preprocessing (intended specifically to render them independent), the a priori probability is 1/(2ˆ10 000), i.e. of the order of e-3000, which amounts to saying that it is theoretically possible to recognize 10ˆ3000 different objects. In practice, it will not be possible to make full use of this performance, because purporting to recognize each of these objects would presuppose that one is certain of each of the pixels of the acquisition, or that the a posteriori probability is equal to 1. This is not the case since analog information that is fairly dependent on the observation conditions is accessed, and since provision must therefore be made for a comparison procedure and a decision threshold that are suited to the acquisition made.

The comparison procedure of the invention takes account of the nature of the acquisitions that take the form of images. A conventional procedure for comparing images is the correlation of the raw images or those arising from a preprocessing intended to normalize them. A correlation is a global comparison of the images, and one decides that two images are identical if the correlation maximum is greater than a given threshold. The choice of the threshold has a significant impact in the a priori probability: if working on binary signals of length 1000 bits and if the threshold is fixed at 0.5, the a priori probability goes from 10ˆ-301 to 10ˆ-58. In practice, and for reasons of robustness, it is often necessary to fix the decision threshold at a substantially lower value, that is to say to tolerate a much bigger error percentage. However, for the example of signals 1000 bits long, a correlation with a threshold fixed at 0.1 leads to a priori probability of 10ˆ-3. It is thus seen that with these methods, it is not unreasonable to start from images comprising around 10 000 independent pixels. Another factor reducing the performance is the fact the location of the image is not perfectly defined. One is therefore led to consider not only the “central” correlation product, but also the correlation products corresponding to translations of images within a given bracket.

A first embodiment of a reader in accordance with the invention will be described with reference to FIG. 1. This reader 1 comprises a laser source 2, for example a monomode laser diode, considered to be a point source 2a followed by a lens 3 at the image focus 4 of which is formed the image of the source 2a. The focus 4 coincides with the object focus of a second lens 5 of short focal length (for example 4 mm) whose optical axis is perpendicular to that of the lens 3. The image focus of the lens 5 coincides with the surface of the object 6 to be examined. The lens 5 is immediately followed by a diaphragm 7. The focus 4 is brought onto the oblique splitting face of a polarization splitter cube 8. Perpendicularly to the optical axis of the lens 5, on the opposite side from the object 6 with respect to the cube 8, is disposed a detector 9.

In this device 1, the lens 3 forms an image of the source point 2a at the object focus of the lens 5. Thus, the beam 10 illuminating the object 6 is collimated, and its cross section is determined by the diaphragm 7. The lens 5 forms an image of the illuminated area of the object 6 on the detector 9. On the outward leg, the cube 8 reflects the polarized illumination beam towards the object 6, while in the opposite direction it allows through (without reflecting it) only the beam with polarization orthogonal to the first polarization. Thus, the specular reflection of the object 6 is eliminated or greatly reduced.

The numerical aperture of the reading system 1 and the value of its optical magnification are chosen in such a way that the size of the grains of the speckles is greater than that of the pixels of the detector 9, so as to avoid aliasing phenomena that will impair the quality of recognition. By way of example, it is possible to work on an object field having dimensions of the order 500 μm×500 μm. If the useful surface area of the detector 9 is 5 mm×5 mm, the optical magnification may be 10 times. If the detector 9 comprises a matrix of 256×256 pixels, it will be possible to sample correctly only 10.e4 grains of speckles. The resolution of the reading system is intentionally limited to 5 μm in the object plane, for example by limiting the numerical aperture to 0.1 with the aid of the diaphragm 7.

The reader 1 also comprises means of accurate positioning (not represented) of the object 6 as well as means of calculation (not represented) making it possible to compare the digital image observed with the image expected (recorded) for the object to be verified. Advantageously, the system 1 also comprises means of reading (not represented) of the information contained on the surface or in the interior of the object 6 (magnetic track, electronic chip, optical storage area, bar code, etc.).

Represented in FIG. 2 is another embodiment 10 of the pptical device of the reading system of the invention in this figure, elements similar to those of FIG. 1 are assigned like numerical references. The main difference with respect to the device of FIG. 1 resides in the fact that the optical axes of the lenses 3 and 5 coincide, these two lenses being disposed on either side of the splitter cube 8, between the object 6 and the detector 9. The laser source 2 illuminates the oblique face of the cube 8 directly, and it is situated at the object focus of the lens 3 (taking account of the reflection of the laser beam on the oblique face of the cube 8).

With reference to FIG. 3 an embodiment of the recording system in accordance with the invention will be described. In a general manner, the recording system is similar to the reading system. The difference between them resides chiefly in the means making it possible to vary, when recording, various critical parameters which may differ from one reading system to another (these reading systems should generally be cheap, since they are produced in large batches, and hence their characteristics are not identical from one system to another). These critical parameters are in particular the wavelength of the laser source, the focusing distance, the positioning of the object to be examined. This recording system, which is one-off, or produced in small batches, should be of better quality than the reading systems. It serves to record as many reference speckle images as there are combinations of critical parameters to be considered and that may vary. The whole sets of these patterns constitutes the reference database that allows successful authentication or identification.

In FIG. 3, elements similar to those of FIGS. 1 and 2 are assigned like numerical references. The device 11 of FIG. 3 comprises the same optical imaging device of that of FIG. 2, namely the lenses 3 and 5 with coincident optical axes and disposed on either side of the splitter cube 8. The laser source 2 is disposed at the object focus of the lens 3. The diaphragm 7 is disposed immediately after (in the outward direction of the beam of the laser source) the lens 3. The object 6a (one seeks to verify whether it is actually authentic, that is to say the object 6 itself, that served to produce the database) is placed in the same manner as the object 6. Furthermore, represented in FIG. 3 is an actuator 12 which serves to very finely vary (by a few microns or tens of microns, for example) the focusing distance of the laser beam on the object 6a, by varying, for example, the position of the lens 3. It is also possible to vary the aperture of the diaphragm 7. Of course, other means (not represented) make it possible to vary the other critical parameters of the recording system (laser wavelength, etc., as specified hereinabove).

The images recorded in the database may be raw images provided by the detector of the recording system. However, the invention makes provision to record preprocessed images, preferably in compressed form, in particular when the database must comprise a large number of images. The preprocessing may be borne out in numerous ways. On account of the fact that the Fourier transform of the image (obtained for example by FFT) is well suited to recognition by reading, it is one of the preferred preprocessing procedures of the invention. In order to normalize the reference image thus obtained, it is divided by its modulus, that is to say only its phase information is preserved, this amounting to performing a “whitening” operation on the spectrum of the image. Moreover, in order to conserve only the reproducible part of the information, the values corresponding to the low spatial frequencies are removed, these comprising terms related to the object (with average reflectivity), to the illumination (so as to avoid inhomogeneities of the illumination beam), and which may also comprise spectral aliasing residues. The values corresponding to the high spatial frequencies, whose signal-to-noise ratio is lower, are also removed. The values retained are coded with as low as possible a number of bits, without however reducing the recognition probability too much. It is necessary to find, depending on the level of security sought, and depending on the desired maximum volume of the database, a compromise between the number of values retained for each reference and the dynamic range of the references. Represented in FIG. 4 is an exemplary spectral domain adopted to construct a reference database. In this FIG. 4, the coordinate axes are graduated as normalized values of spatial frequencies of the speckle patterns, in x and in y. The contour 13, defined for frequencies below half the normalized spatial frequency, encompasses the whole set of spatial frequencies of the image, and delimits a closed surface 14 (shaded) inside which has been plotted an exemplary spectral domain adopted 15 (hatched) contained in the surface 14.

Other image transformations, leading to a reduction in the size of the database with a reduced loss of information may be implemented within the framework of the invention, for example wavelet transforms or cosine transforms. As in the conventional image compression procedures, only a certain number of coefficients of the transform are retained from among the most significant. Given the fairly uniform spectrum of these images that is very different from that of the natural images, the components to be retained can be chosen a priori, as specified for the method described hereinabove, and contrary to what is conventionally done in image coding-compression.

The method of the invention proceeds in the following manner in respect of local authentication. The reading system possesses the public key that allows it to read and to decrypt on the card the signature of the speckle image. After a preprocessing intended to isolate the useful area of the image, a comparison is made between the optical signature observed and the signature stored on the card. This comparison may be done according to a conventional procedure termed “pattern matching”, for example by a correlation between the image observed and the reference image, as specified hereinabove. Given the well-known properties of the correlation, if the reference image was stored in the form of spectral components, as specified hereinabove, the comparison operation consists essentially in taking the Fourier transform of the observed image and in calculating the product of the spectral components retained times those of the reference. The result of the operation is then compared with a threshold to decide on authenticity.

According to an alternative form of the method of the invention, the authenticity decision is taken preferably with the aid of a hybrid criterion weighting several results, for example:
the logarithm of the deviation between the amplitude of the correlation peak and a predefined threshold,
the distance between the current position of the correlation peak and the nominal position,
the variance of these data over several successive measurements.

The determination of the position of the correlation peak requires taking the inverse Fourier transform of the product of the image and of the reference, this being more expensive in terms of calculation power. On the other hand, the conjoint use of these various data makes it possible to avoid false alarms and to evaluate the likelihood of the measurement before decision taking. If the comparison fails, the reader can recommence the operation after having modified a parameter, for example the wavelength of the laser source.

A variant of the method of authentication according to the invention consists in effecting the authentication on a site remote from the readers, for example at the location of a server linked to the various readers and to a recorder. The authentication step is borne out using the database recorded during the recording step. According to this variant, the optical signature of the speckle image and the reference of the object are provided, as well as the parameters of the reader. The server performs the comparison between the optical image as read by a reader and the reference image of the object corresponding to the parameters provided to the server.

Advantageously, the invention makes provision to perform periodically or with each use of a reader, calibrations of the various parameters required for authentication, in particular the critical parameters. These calibrations are done with the aid of one or more speckle images of calibration objects. As a variant, the calibration object may be the support of the reading system. The parameters of the reader that is used are determined locally or by the server to which it is linked.

According to another aspect of the method of the invention, authentication is performed on the basis of interrogation of a reader. In this case, the reader in question comprises a focusing lens (lens 5 of the embodiments described hereinabove) mounted on actuators allowing displacements in one or two directions of the plane perpendicular to the optical axis of the lens. Advantageously, these actuators allow automatic and accurate adjustment of focusing. A speckle image of the observed area of the object is formed on the two-dimensional sensor of the detector (detector 9). The authentication process is then implemented in the following manner.

The object observed, for example a card for accessing a protected place, is prepositioned under the lens of the optical reader, by virtue of a suitable mechanical guiding device. The speckle image is transmitted to the validation device at the same time as the identification data borne by the card or provided by the bearer of the card. The validation device compares the speckle image received with the image corresponding to the object reference (stored in the validation device or transmitted from a database). If the object is indeed the one which is declared, the result of a comparison is positive. If the comparison is based on a correlation, data of positioning of the object with respect to the sensor are provided to the validation device. These data constitute a measure of the error of positioning of the object under the sensor. They may be provided to the object positioning devices so as to make possible to perform a correction of the position of the object. In this case, a second measurement, performed after such a positioning correction, should improve the recognition quality and allow practically certain authentication of the object.

If the second measurement provides results inconsistent with those of the first (for example if the new position error found is not close to zero or if the result is not appreciably improved), it is highly probable that the object examined is not the right one.

In order to increase the robustness of the authentication method, it is possible to “interrogate” the reader. The “zero” position having been determined in accordance with the steps setforth hereinabove, the reader may be asked to position itself on a point whose coordinates will have been drawn at random from among a determined set of values. The reader must then be able to provide a speckle image corresponding to that recorded in the database for these observation coordinates and this object. The probability of false acceptance is thus substantially diminished. Conversely, this same process can be implemented to confirm the acceptance of an object on a first doubtful recognition result. The coordinates explored may be those of a plane perpendicular to the optical axis of the focusing lens (lens 5) or the coordinate along this optical axis (that is to say a translation of the focusing plane parallel to itself, according to the number of degrees of freedom of said actuators.

This manner of bearing out the authentication has several advantages. The first is that the system is made more tolerant to positioning errors or to deformations of the object. The second is that the comparison is done on a more extensive area of the object, thereby making it more difficult to copy, and safeguarding the system from operating problems related to local degradation of the object (which may occur with frequently handled objects, which may be scratched, punctured, etc.). The third is that the reader is able to respond to an unforeseen demand on the system (which randomly draws the coordinates of the point to be observed), this making piracy of the reading device more complex, using a hardware or software device that would respond in its stead. In this case the pirate would have to be able to access all the data on the surface or in the active volume of the object.

As a variant of the method of the invention, the focusing device can use an auxiliary beam focused onto the surface of the object to be examined. The focusing error detector can, in this case, be of a known type, such as the astigmatic sensor often used in reading heads for optical disks. However, it may be simpler to directly observe the speckle signal which serves to authenticate the object. A possible method consists in placing the object in its most probable focusing position, in performing the comparison with the expected speckle pattern, then in slightly varying this position. The variation of the result of the comparison makes it possible to evaluate the correction to be made to the position of the objective in order to increase the quality of the result, and hence to get closer to the best focusing position, this being akin to the gradient procedure.

In the foregoing, the optical device was considered to be designed in such a way as to produce on the detector an image of the useful area of the object. This device can, as a variant, operate if the detector is not in the image plane of the optical device. The detector can then be in a plane conjugate to the plane of the pupil of the optical device, which is the Fourier plane of the illuminated object. In this case, the spatial filtering of the speckles, complying with the Shannon's sampling conditions may be done either by limiting the dimension of the illumination spot on the object, or by applying a diaphragm to an intermediate image plane. It has been found that the arrangement of the sensor on an “intermediate” plane (between the image plane and the Fourier plane) can represent a better compromise in the design of the system in relation to the adaptation of the size of the speckle grains to the spatial resolution of the detector.

In what was set forth hereinabove, the illumination of the object was considered to be uniform and collimated. The system of the invention also operates even when these conditions are not complied with.

Represented in FIG. 5 is the simplified diagram of a recording device in accordance with the invention, in which the recording is done by a method of electronic holography. In this device 16, the laser source 17 is placed at the object focus of a collimating lens 18 which is followed by a splitter cube 19 whose semi-reflecting oblique face it illuminates. Part of the parallel beam emanating from the lens 18 passes through this oblique face and arrives perpendicularly on a mirror 20 moved by a piezoelectric actuator. The beam reflected by the mirror 20 arrives on the oblique face of the cube 19, from which face it is reflected towards a detector 21. The part of the beam emanating from the lens 18 which does not pass through the oblique face of the cube 19 is reflected towards the object to be examined 22 a diaphragm 23. The part of the parallel beam emanating from the lens 18, which is returned to the detector 21, serves as reference beam for the holographic detector device. The detector 21 therefore receives illumination consisting of the combination of the reference beam and a beam backscattered by the object 22 (which passes directly through the cube 19). According to a well known technique, several histograms thus obtained are recorded, each time varying the optical path length of the reference beam by virtue of the actuator of the mirror 20. According to the technique used, three or four images of intensity corresponding to variations of path length of k.2π/3 or of k.π/2 are recorded. On the basis of these acquisitions it is possible to extract the complex field scattered by the object. It is then possible, by applying the well-known laws of the formation of images, to calculate images of intensity corresponding to that which would be observed by a conventional optical device comprising a simple lens and an intensity detector, such as a CCD, placed at well-defined positions.

The benefit of this method is that it records a holographic image of the object, thereby making it possible to recalculate the image such as it would be viewed by an observation device with characteristics differing slightly from the nominal characteristics. However if the illuminated medium of the object is highly scattering, it will nevertheless be necessary to record holograms corresponding to the various possible wavelengths for the observation, since, the paths of the light beam being multiple, the backscattered field does not depend in a simple manner on the observation wavelength.

1. A method of optical authentication and identification of objects, comprising:
illuminating with coherent light a volume-wise at least partially scattering surface of reference objects under specified illumination conditions,
recording the speckle patterns thus obtained for various nominal values of illumination parameters and also in a range of values around these nominal values, then,
upon the verification of other objects or of the same objects, in illuminating these objects under the same nominal conditions and
comparing each time the speckle pattern thus obtained with those which were recorded and
retaining the objects if their speckle pattern corresponds to one of those that was recorded.

2. The method as claimed in claim 1, wherein the parameters are one at least of the following parameters: wavelength of illumination of the objects, distance of focusing on the reference object, position of the illumination source, orientation of the objects.

3. The method as claimed in claim 1, wherein the speckle patterns are preprocessed before recording.

4. The method as claimed in claim 3, wherein the preprocessing consists in compressing the images.

5. The method as claimed in claim 4, wherein the compression consists in performing at least one of the following operations: Fourier transform, fast Fourier transform, wavelet transform, cosine transform.

6. The method as claimed in claim 5, wherein the image is normalized, preserving only its phase information.

7. The method as claimed in claim 5, wherein the preprocessing also consists in removing from the images the values corresponding to the low spatial frequencies and to the high spatial frequencies.

8. The method as claimed in claim 1, wherein the comparison of the speckle patterns is done by correlation.

9. The method as claimed in claim 8, wherein the decision of a comparison is taken on the basis of criteria weighting at least one of the following results:
the logarithm of the deviation between the amplitude of the correlation peak and a predefined threshold,
the distance between the current position of the correlation peak and the nominal position, and
the variance of these data over several successive measurements.

10. The method as claimed in claim 1, wherein a database of reference patterns is constructed and the authentication or identification is performed using this database.

11. The method as claimed in claim 1, wherein a calibration of the readers is performed with the aid of a calibration image so as to determine the critical parameters.

12. The method as claimed in claim 1, wherein the authentication or identification is borne out by interrogating a reader.

13. The method as claimed in claim 1, wherein the recording of the speckle patterns is done by holography.

14. The method as claimed in claim 1, wherein the characteristics of the optical part of the reader are adjustable and the positioning error, if any, of the object is corrected while tending to reduce measurement error.

15. The method as claimed in claim 14, wherein the “zero” position of the reader having been determined, the reader is positioned according to coordinates drawn at random and the speckle image obtained is compared with the image which ought theoretically to be obtained.

16. The method as claimed in claim 1, wherein information identifying the object of another nature is recorded in addition to the speckle images.

17. The method as claimed in claim 16, wherein the identification information is contained on the surface or in the interior of the object.

18. The method as claimed in claim 17, wherein the identification information is borne by at least one of the following supports: magnetic track, electronic chip, optical storage area, and bar code.

19. A device for the optical authentication and identification of objects, comprising:
an optical recording device with laser source,
a storage device and an optical reading device with laser source, whose illumination beam illuminates the objects and whose optical device forms on the detector of the reading device
an image of the illuminated area of these objects, parameters of these optical devices being modifiable.

20. The device as claimed in claim 19, wherein the modifiable parameters are at least one of the following parameters: wavelength of the laser source, direction of emission of the laser beam, focusing of the laser beam, position of the laser source, inclination and position of the object with respect to the laser beam.
